(19) United States
(12) Patent Application Publication
(10) Pub. No.: US 2016/0021770 A1
(43) Pub. Date: Jan. 21, 2016

(54) CABINET HAVING AN ENVIRONMENT MONITORING FUNCTION

(71) Applicant: CyberPower Systems, Inc., Taipei City (TW)

(72) Inventor: Hung-Chun CHIEN, Taipei City (TW)

(21) Appl. No.: 14/331,619

(22) Filed: Jul. 15, 2014

(51) Int. Cl. H05K 5/02

(52) U.S. Cl. CPC H05K 5/0247

(57) ABSTRACT

A cabinet includes a cabinet body defining therein an accommodation chamber for accommodating electronic machines such as servers, modems, switching systems, routers and/or other IT (information technology) equipment and machines, a monitoring system main unit mounted in the accommodation chamber of the cabinet body and having signal lines thereof arranged along horizontal top surface and vertical lateral surfaces of an inside wall of the cabinet body, a plurality of connection interfaces respectively connected to the signal lines remote from the monitoring system main unit, and different sensors respectively connected to the connection interfaces to face toward the servers, modems, switching systems, routers and/or other IT (information technology) equipment and machines in the accommodation chamber for monitoring temperature, humidity, smoke, airflow, air pressure, contact closure and/or access control.

### BACKGROUND OF THE INVENTION

1. Field of the Invention

The present invention relates to cabinets and more particularly, to a cabinet having an environment monitoring function that has a monitoring system main unit mounted in the cabinet body thereof and a plurality of connection interfaces respectively electrically connected to respective signal lines of the monitoring system main unit and fixedly disposed at different locations inside the cabinet body for the installation of different sensors for monitoring temperature, humidity, smoke, airflow, air pressure, contact closure and/or access control.

2. Description of the Related Art

With the continuous improvement of socio-economic, national income has been continuously increased. In consequence, small and medium-sized enterprises as well as large-sized companies are more likely to be active. Further, company staffs need to use telecommunication equipment for operating electronic machines such as telephones, network systems and/or servers for industrial computers. Further, enterprises and companies normally will gather various electronic machines like servers, modems, switching systems, routers and/or other IT (information technology) equipment and machines in a cabinet. However, in order to keep normal and safety functioning of all kinds of electronic machines, including servers, modems, switching systems, routers and/or other IT (information technology) equipment and machines in an electronic machine cabinet, it is necessary to monitor the temperature, humidity, smoke, airflow, air pressure, contact closure, access control, and other fire protection safety conditions (such as flood or fire) so that any abnormality can be solved immediately when it is found.

In order to monitor various conditions in and around an electronic machine cabinet, the user may install monitors and sensors at different locations around the electronic machine cabinet. However, according to conventional methods, this monitoring work must keep running round the clock under the control of a person, consuming much labor. This monitoring method cannot eliminate human error. When an unexpected condition occurs and is not found due to human error, the problem cannot be solved immediately after its occurrence. Some electronic machine cabinet providers may install different sensors in the electronic machine cabinets for monitoring various conditions. However, prior to mounting sensors inside an electronic machine cabinet, a wiring work is necessary. When a large number of sensors are to be installed in an electronic machine cabinet, the wiring work will be complicated and very time consuming and labor intensive. Further, it is not easy to control sensor locations, to manage installed sensors, or keep installed sensors in accurate alignment with respective electronic machines in the electronic machine cabinet for monitoring temperature, humidity, smoke, airflow, air pressure, contact closure and other conditions accurately.

### SUMMARY OF THE INVENTION

The present invention has been accomplished under the circumstances in view. It is therefore the main object of the present invention to provide a cabinet having an environment monitoring function that comprises a cabinet body, which comprises an accommodation chamber surrounded by an inside wall thereof for accommodating electronic machines including telecommunication equipment and machines, a monitoring system main unit mounted in the accommodation chamber inside the cabinet body and comprising a plurality of signal lines arranged along the inside wall of the cabinet body, and a plurality of connection interfaces respectively electrically connected to the signal lines remote from the monitoring system main unit and disposed at different locations in the accommodation chamber for the installation of different sensors for monitoring temperature, humidity, smoke, airflow, air pressure, contact closure and/or access control. After establishment of the cabinet body, the arrangement of the signal lines of the monitoring system main unit is done, and no further wiring work will be necessary.

Preferably, the signal lines are arranged along horizontal top surface and vertical lateral surfaces of the inside wall of the cabinet body and exposed to the accommodation chamber. Further, the signal lines can be affixed to said horizontal top surface and vertical lateral surfaces of the inside wall of the cabinet body using an adhesive, wire pressing strips, cable holders and/or cable clips.

Further, extension lead wires can be used and respectively electrically extended from the connection interfaces for electrically connecting different sensors to the connection interfaces, enabling the sensors to be disposed at locations relatively closer to respective electronic machines in the accommodation chamber inside the cabinet body and at respective optimal angles to enhance the sensing accuracy in monitoring the temperature, humidity, smoke, airflow, air pressure, contact closure and/or access control in and around the cabinet body.

### BRIEF DESCRIPTION OF THE DRAWINGS

FIG. 1 is a perspective view of a cabinet in accordance with the present invention.

FIG. 2 is another perspective view of the cabinet in accordance with the present invention.

FIG. 3 is an operational flow chart of the monitoring system main unit of the cabinet in accordance with the present invention.

FIG. 4 is a sectional rear side view of the cabinet in accordance with the present invention.

### DETAILED DESCRIPTION OF THE PREFERRED EMBODIMENT

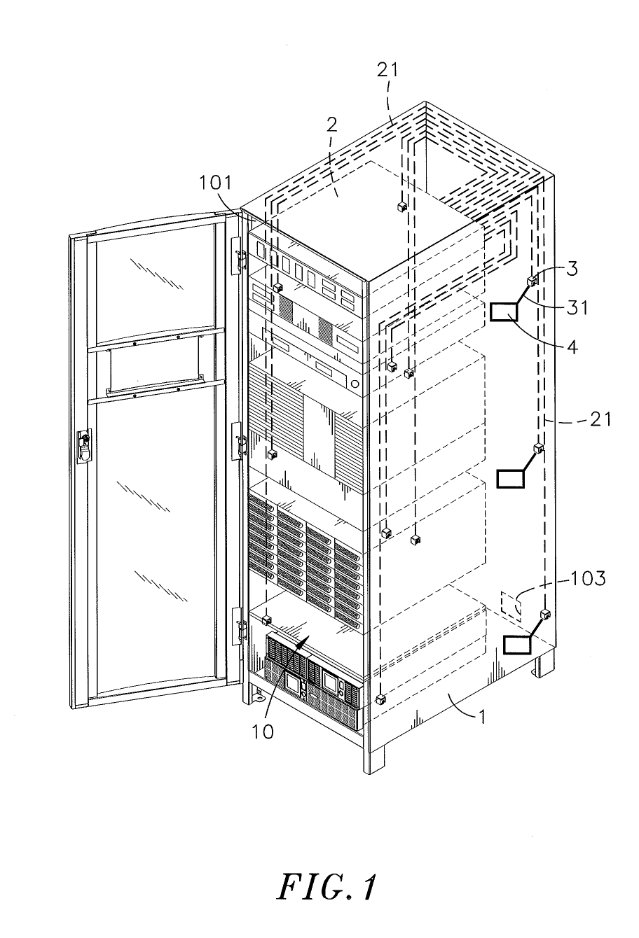

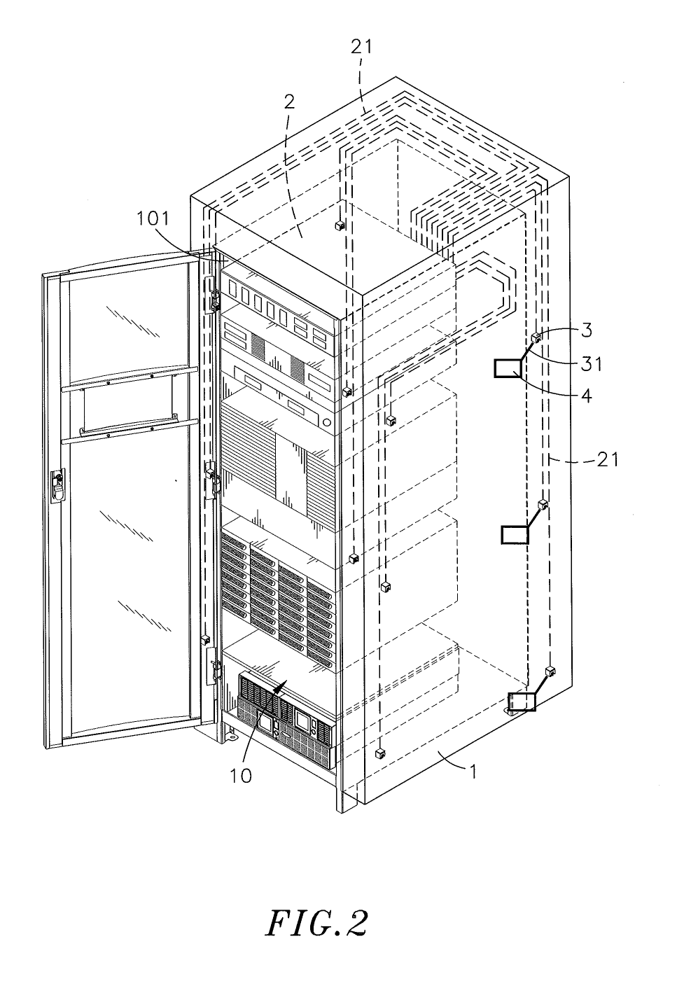

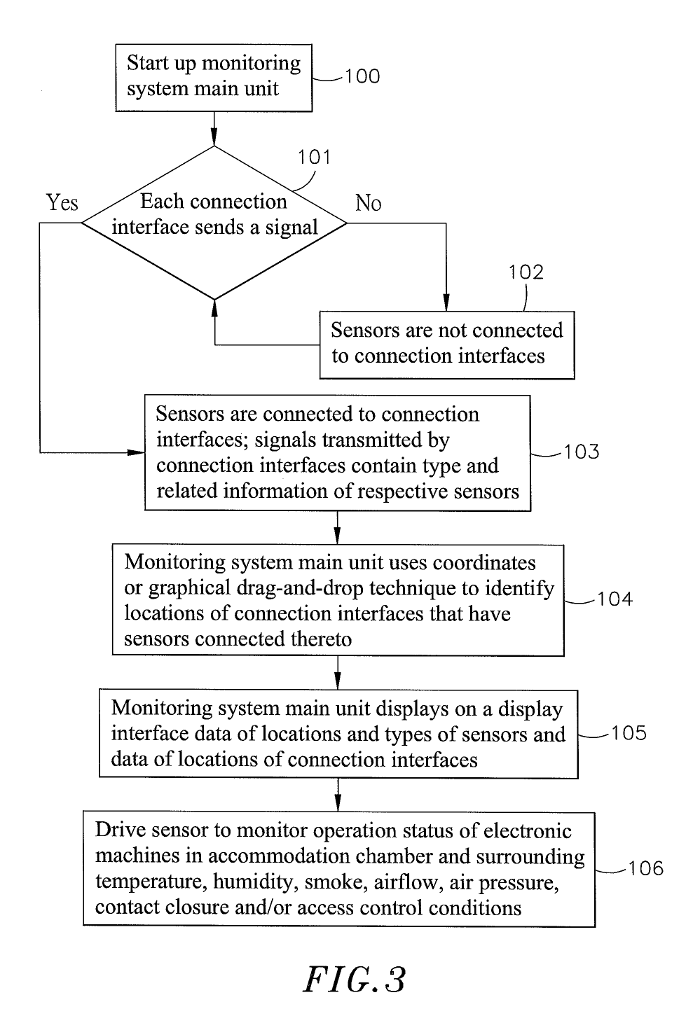

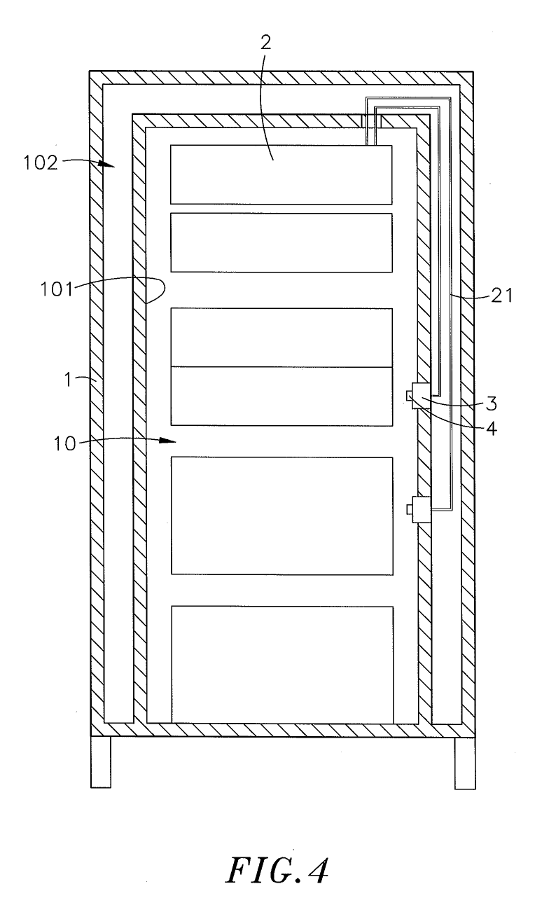

Referring to FIGS. 1-4, a cabinet having an environment monitoring function in accordance with the present invention is shown. The cabinet comprises a cabinet body 1, a monitoring system main unit 2, and a plurality of connection interfaces 3.

The cabinet body 1 defines therein an accommodation chamber 10 adapted for accommodating various electronic machines such as servers, modems, switching systems, routers and/or other IT (information technology) equipment and machines.

The monitoring system main unit 2 has electrically connected thereto a plurality of signal lines 21. The connection interfaces 3 are respectively connected to the signal lines 21 remote from the monitoring system main unit 2. Further, the connection interfaces 3 can be plug type or socket type electric connectors.

During installation of the present invention, mount the monitoring system main unit 2 in the accommodation chamber 10 inside the cabinet body 1 to let the signal lines 21 be arranged along the inside wall 101 of the cabinet body 1 and the connection interfaces 3 be fixedly mounted in the peripheral wall of the cabinet body 1 at different elevations to face toward the accommodation chamber 10 for the mounting of different sensors 4.

Further, the signal lines 21 are arranged along the horizontal top surface and vertical lateral surfaces of the inside wall 101 of the cabinet body 1 and affixed thereto using an adhesive, wire pressing strips, cable holders, cable clips. After installation, the connection interfaces 3 are fixedly arranged on the inside wall 101 of the cabinet body 1 at different elevations within the accommodation chamber 10, and sensors 4 are respectively connected to the connection interfaces 3 to face toward different electronic machines, such as servers, modems, switching systems, routers and/or other IT (information technology) equipment and machines that are accommodated in the accommodation chamber 10 at different elevations. These sensors 4 are adapted for monitoring temperature, humidity, smoke, airflow, air pressure, contact closure and/or access control. Alternatively, the sensors 4 can be arranged to face toward the outside of the cabinet body 1 for monitoring the surrounding temperature, humidity, smoke, airflow, air pressure, contact closure and/or access control outside the cabinet body 1. Thus, in case an unexpected disaster (flooding, fire or earthquake) or severe weather event occurs, the maintenance engineer in charge can then take all the necessary steps to maintain normal functioning of all the electronic machines in the cabinet body 1.

Further, the cabinet body 1 can be configured to provide hidden spaces 102 in the inside wall 101 around the accommodation chamber 10 for receiving the signal lines 21, enabling the connection interfaces 3 at the respective distal ends of the signal lines 21 to be disposed outside the hidden spaces 102 to hold the respective sensors 4 at different elevations in respective selected angles for monitoring the temperature, humidity, smoke, airflow, air pressure, contact closure and/or access control in the cabinet body 1 and the surrounding temperature, humidity, smoke, airflow, air pressure, contact closure and/or access control outside the cabinet body 1. For example, the sensors 4 can be configured to provide an alarm signal if the ambient temperature is beyond a predetermined normal temperature range (for example, 20°˜25° C.) due to accumulation of waste heat discharged by the electronic machines in the cabinet, or the ambient humidity is beyond a predetermined normal humidity range (for example, 44˜55%) due to a significant weather change or the occurrence of an unexpected disaster (flooding, fire or earthquake), or a severe weather event (cold snap or typhoon induced airflow or air pressure instability) occurs, or a smoking occurs (due to a fire accident or electronic machine failure), or the contact closure of an access door is opened (due to an intrusion), assuring normal functioning of the electronic machines in the cabinet body 1. Thus, after establishment of the cabinet body 1, the arrangement of the signal lines 21 of the monitoring system main unit 2 is done and no further wiring work will be necessary. After installation of electronic machines in the accommodation chamber 10 inside the cabinet body 1, the connection interfaces 3 and the respective sensors 4 are kept in alignment with the respective installed electronic machines.

Through the sensors 4 and the signal lines 21, the monitoring system main unit 2 starts up a monitoring operation subject to the following steps:
(100) Start up the monitoring system main unit 2 in the accommodation chamber 10 inside the cabinet body 1.
(101) The monitoring system main unit 2 determines whether or not each connection interface 3 has transmitted a signal through the respective signal line 21, and then proceed to step (102) if negative, or step (103) if positive.
(102) The connection interfaces 3 are not electrically connected with respective sensors 4, and then return to step (101).
(103) The connection interfaces 3 are electrically connected with respective sensors 4, and the signals transmitted by the respective connection interfaces 3 contain the type and related information of the respective sensors 4.
(104) The monitoring system main unit 2 uses coordinates or graphical drag-and-drop technique to identify the locations of the respective connection interfaces 3 that have respective sensors 4 electrically connected thereto.
(105) The monitoring system main unit 2 displays the data of the locations and types of the sensors and the data of the locations of the connection interfaces 3 on a display interface thereof.
(106) Drive the sensors 4 to monitor the operation status of the electronic machines in the accommodation chamber 10 inside the cabinet body 1 and surrounding temperature, humidity, smoke, airflow, air pressure, contact closure and/or access control conditions.

Further, the monitoring system main unit 2 can be linked to a remote host (computer, monitor or surveillance system) by a cable or wireless technology, enabling the remote host to perform an auto monitoring and management operation through the cabinet 1 and its internal monitoring system main unit 2, reducing human error and the consumption of time and labor.

Further, the cabinet body 1 has at least one drain hole 103 cut through the inside wall 101 near a bottom side thereof for discharge of water. Further, one connection interface 3 is disposed adjacent to each drain hole 103. The sensor 4 installed in the connection interface 3 adjacent the drain hole 103 is capable of detecting moisture and humidity, and will produce an alarm signal if a flooding or water leakage occurs, enabling the person in charge to remove the cabinet to a safe place or to take the all the necessary steps.

Further, extension lead wires 31 can be used to electrically connect respective sensors 4 to the connection interfaces 3, enabling the sensors 4 to be disposed at locations relatively closer to respective electronic machines in the accommodation chamber 10 inside the cabinet body 1 and at respective optimal angles to enhance the sensing accuracy in monitoring the temperature, humidity, smoke, airflow, air pressure, contact closure and/or access control in and around the cabinet body 1.

As described above, the invention provides a cabinet having an environment monitoring function that comprises a cabinet body 1 that defines therein an accommodation chamber 10 adapted for accommodating various electronic machines such as servers, modems, switching systems, routers and/or other IT (information technology) equipment and machines, a monitoring system main unit 2 having electrically connected thereto a plurality of signal lines 21 that are arranged along horizontal top surface and vertical lateral surfaces of an inside wall 101 of the cabinet body 1 and affixed thereto using an adhesive, wire pressing strips, cable holders, cable clips, a plurality of connection interfaces 3 respectively connected to the signal lines 21 remote from the monitoring system main unit 2 and fixedly arranged on the inside wall 101 of the cabinet body 1 at different elevations within the accommodation chamber 10, and different sensors 4 respectively connected to the connection interfaces 3 to face toward different electronic machines, such as servers, modems, switching systems, routers and/or other IT (information technology) equipment and machines that are accommodated in the accommodation chamber 10 at different elevations for monitoring temperature, humidity, smoke, airflow, air pressure, contact closure and/or access control. After establishment of the cabinet body 1, the arrangement of the signal lines 21 of the monitoring system main unit 2 is done, and no further wiring work will be necessary. After installation of electronic machines in the accommodation chamber 10 inside the cabinet body 1, the connection interfaces 3 and the respective sensors 4 are kept in alignment with the respective installed electronic machines for monitoring the temperature, humidity, smoke, airflow, air pressure, contact closure and/or access control in and around the cabinet body 1. Further, extension lead wires 31 can be used to electrically connect respective sensors 4 to the connection interfaces 3, enabling the sensors 4 to be disposed at locations relatively closer to respective electronic machines in the accommodation chamber 10 inside the cabinet body 1 and at respective optimal angles to enhance the sensing accuracy in monitoring the temperature, humidity, smoke, airflow, air pressure, contact closure and/or access control in and around the cabinet body 1.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A cabinet, comprising:
a cabinet body comprising an accommodation chamber surrounded by an inside wall thereof for accommodating electronic machines;
a monitoring system main unit mounted in said accommodation chamber inside said cabinet body, said monitoring system main unit comprising a plurality of signal lines arranged along said inside wall of said cabinet body and affixed thereto; and
a plurality of connection interfaces respectively electrically connected to said signal lines remote from said monitoring system main unit and disposed at different elevations in said accommodation chamber for the installation of different sensors.

2. The cabinet as claimed in claim 1, wherein said accommodation chamber is configured to accommodate servers, modems, switching systems, routers and/or other IT (information technology) equipment and machines used by electronic products.

3. The cabinet as claimed in claim 1, wherein said signal lines are arranged along horizontal top surface and vertical lateral surfaces of said inside wall of said cabinet body and exposed to said accommodation chamber.

4. The cabinet as claimed in claim 1, wherein said signal lines are affixed to said horizontal top surface and vertical lateral surfaces of said inside wall of said cabinet body using an adhesive, wire pressing strips, cable holders and/or cable clips.

5. The cabinet as claimed in claim 1, wherein said cabinet body further comprises a plurality of hidden spaces defined in said inside wall around said accommodation chamber for receiving the passing of said signal lines, enabling said connection interfaces to be disposed outside said hidden spaces to hold respective sensors at different elevations in respective selected angles.

6. The cabinet as claimed in claim 1, wherein said connection interfaces are selected from the group of plug type and socket type electric connectors.

7. The cabinet as claimed in claim 1, further comprising a plurality of sensors respectively installed in said connection interfaces at different elevations for monitoring temperature, humidity, smoke, airflow, air pressure, contact closure and/or access control.

8. The cabinet as claimed in claim 1, further comprising a plurality of extension lead wires respectively electrically extended from said connection interfaces and adapted for electrically connecting different sensors to said connection interfaces.
